(19) United States
(12) Patent Application Publication
(10) Pub. No.: US 2024/0203944 A1
(43) Pub. Date: Jun. 20, 2024

(54) THREE-DIMENSIONAL SEMICONDUCTOR DEVICE

(71) Applicant: SAMSUNG ELECTRONICS CO., LTD., Suwon-si (KR)

(72) Inventors: Jae Seung CHOI, Suwon-si (KR); Byung-Su Kim, Suwon-si (KR)

(73) Assignee: SAMSUNG ELECTRONICS CO., LTD., Suwon-si (KR)

(21) Appl. No.: 18/370,650

(22) Filed: Sep. 20, 2023

(30) Foreign Application Priority Data
Dec. 20, 2022 (KR) 10-2022-0179511

(51) Int. Cl. H01L 25/065

(52) U.S. Cl. CPC H01L 25/0657; H01L 2225/06513; H01L 2225/06541

(57) ABSTRACT

A semiconductor device includes a first die including a plurality of first micro bumps on a first upper face of the first die, a plurality of first macro metal pads at positions respectively corresponding to the plurality of first micro bumps, a first routing wiring layer comprising a plurality of first routing metals, where a first end of each of the plurality of first routing metals is respectively under the plurality of first macro metal pads, a plurality of through silicon vias (TSVs), where first ends of the plurality of TSVs are respectively connected to second ends of the plurality of first routing metals, and where each of the plurality of TSVs extends downward from the respective second ends of the plurality of first routing metals, a first plurality of keep-out zones including a first keep-out zone bundle region, and a plurality of first micro metal pads.

### CROSS-REFERENCE TO RELATED APPLICATION

This application is based on and claims priority to Korean Patent Application No. 10-2022-0179511, filed on Dec. 20, 2022 in the Korean Intellectual Property Office, the disclosure of which is incorporated herein by reference in its entirety.

### BACKGROUND

### 1. Field

Example embodiments of the disclosure relate to a semiconductor device, and in particular, to a three-dimensional semiconductor device including an inter-die interface.

### 2. Description of Related Art

Recently, a system in package (SIP) in which a plurality of semiconductor devices is mounted in one package is being developed. In order to reduce an area occupied by the semiconductor devices in the package and to achieve high-speed communication between the semiconductor devices, development of a three-dimensional semiconductor integrated circuit in which a plurality of semiconductor devices are vertically stacked using a through silicon via (TSV) may be implemented.

The three-dimensional semiconductor integrated circuit in which the plurality of semiconductor devices are vertically stacked may occupy a smaller area. However, from a design point of view, there are difficulties in arranging the devices and wirings in order to integrate the devices in a multilayer stack.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a three-dimensional semiconductor device in which an inter-die interface of a template pattern is disposed to simplify interconnection between layers while reducing design complexity of each layer.

One or more example embodiments provide a semiconductor device including an inter-die interface with an improved degree of freedom of place and routing (PnR) without wasting the area of a die.

Additional aspects will be set forth in part in the description which follows and, in part, will be apparent from the description, or may be learned by practice of the presented embodiments.

According to an aspect of an example embodiment, a semiconductor device may include a first die including a plurality of first micro bumps on a first upper face of the first die, a plurality of first macro metal pads at positions respectively corresponding to the plurality of first micro bumps, a first routing wiring layer comprising a plurality of first routing metals, where a first end of each of the plurality of first routing metals is respectively under the plurality of first macro metal pads, a plurality of through silicon vias (TSVs), where first ends of the plurality of TSVs are respectively connected to second ends of the plurality of first routing metals, and where each of the plurality of TSVs extends downward from the respective second ends of the plurality of first routing metals, a first plurality of keep-out zones including a first keep-out zone bundle region, and a plurality of first micro metal pads in the first keep-out zone bundle region and respectively under second ends of the plurality of TSVs, where a first area size of the first keep-out zone bundle region may be smaller than a total area size of the first plurality of keep-out zones.

According to an aspect of an example embodiment, a three-dimensionally stacked semiconductor device may include a plurality of first micro bumps arranged in an M×N array on an upper face of a bottom die, where each of M and N is a natural number of 1 or greater, a plurality of first macro metal pads respectively corresponding to the plurality of first micro bumps, such that the plurality of first micro bumps are on respective upper faces of the plurality of first macro metal pads, a first routing wiring layer comprising a plurality of first routing metals, where a first end of each of the plurality of first routing metals is radially arranged under the plurality of first macro metal pads, respectively, a plurality of TSVs, where first ends of the plurality of TSVs are respectively connected to second ends of the plurality of first routing metals, and where each of the plurality of TSVs extends downward from the respective second ends of the plurality of first routing metals, and a plurality of first micro metal pads in a first keep-out zone bundle region and respectively under the second ends of the plurality of TSVs, where a first area size of the first keep-out zone bundle region may be smaller than a total area size of the plurality of first macro metal pads.

According to an aspect of an example embodiment, a semiconductor device may include a first bottom die, a first upper die on an upper face of the first bottom die, and a first interface region between the first upper die and the first bottom die, where the first interface region may include a plurality of first micro bumps on the upper face of the first bottom die, a plurality of first macro metal pads on respective upper faces of the plurality of first macro metal pads, where adjacent first macro metal pads of the plurality of first macro metal pads are spaced from each other by a first spacing, a first routing wiring layer comprises a plurality of first routing metals, where first ends of the plurality of first routing metals are respectively and radially disposed under the plurality of first macro metal pads, a plurality of TSVs respectively extending downward from second ends of the plurality of first routing metals, where first ends of the plurality of TSVs are respectively connected to the second ends of the plurality of first routing metals, and a plurality of first micro metal pads in a first keep-out zone bundle region and respectively under second ends of the plurality of TSVs, where adjacent first micro metal pads of the plurality of first micro metal pads may be spaced from each other by a second spacing and where the second spacing may be smaller than the first spacing.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a bottom-die of a three-dimensional semiconductor device according to some embodiments;

FIG. 2 is a diagram illustrating one embodiment of a bottom-die of FIG. 1 according to some embodiments;

FIG. 3 is a top view illustrating a bottom-die according to some embodiments.

FIGS. 4, 5 and 6 are top views illustrating bottom-dies according to some embodiments;

FIG. 7 is a top view illustrating a bottom-die according to some embodiments;

FIG. 8 is a diagram illustrating a three-dimensional semiconductor device according to some embodiments;

FIG. 9 is a cross-sectional view showing an interface region of FIG. 8 according to some embodiments;

FIG. 10 is a diagram illustrating an interface region of a semiconductor device according to some embodiments; and

FIG. 11 is a cross-sectional view illustrating an interface region of a semiconductor device according to some embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, three-dimensional directions are expressed as X-axis, Y-axis, and Z-axis directions for convenience of illustration. The directions as shown are relative, and the present disclosure is not limited thereto. The three-dimensional directions may be expressed as Z-axis, Y-axis, and X-axis directions, or X-axis, Z-axis, and Y-axis directions. However, in each embodiment, the three-dimensional directions are expressed as X-axis, Y-axis, and Z-axis directions.

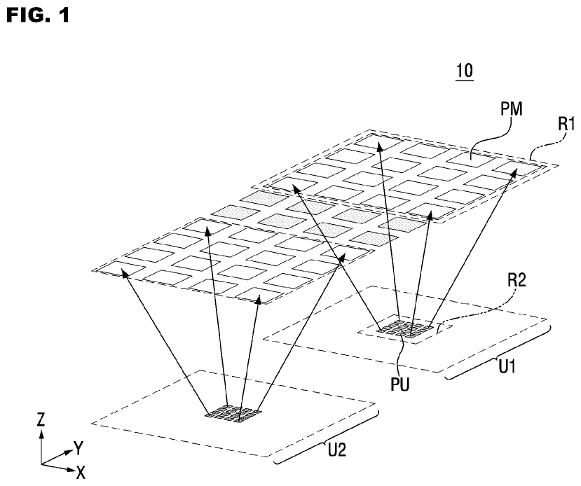

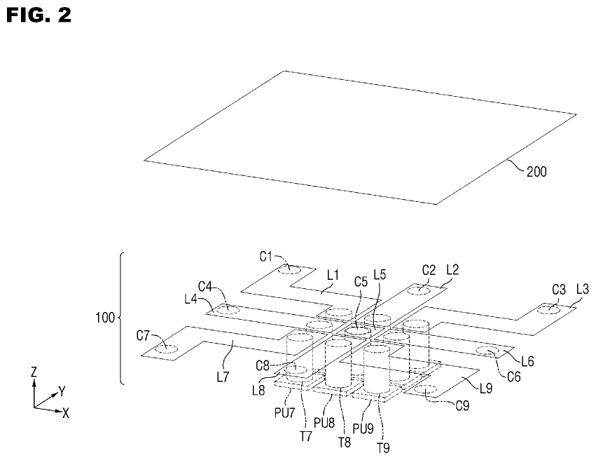

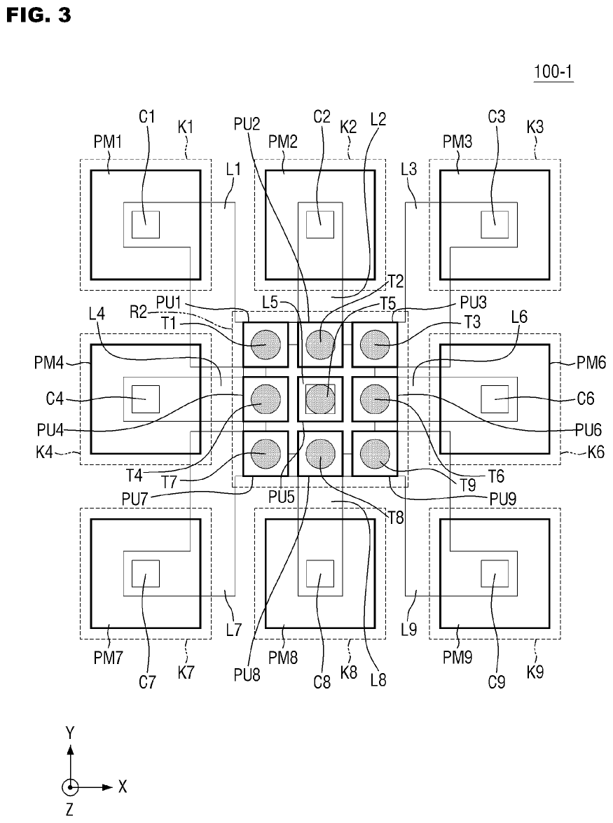

FIG. 1 is a diagram illustrating a bottom-die of a three-dimensional semiconductor device according to some embodiments. FIG. 2 is a diagram illustrating one embodiment of a bottom-die of FIG. 1 according to some embodiments. FIG. 3 is a top view illustrating a bottom-die according to some embodiments.

Referring to FIG. 1, FIG. 2 and FIG. 3, the three-dimensional semiconductor device may include a bottom-die 100 and a top-die 200 vertically stacked, where the top-die 200 may be stacked on an upper face of the bottom-die 100.

An upper die of two dies facing each other vertically may be referred to as a top-die and a lower die thereof may be referred to as a bottom-die. The bottom-die 100 may be referred to as a first die, and the top-die 200 may be referred to as a second die, or vice versa.

Each of inter-die interface regions U1 and U2 according to some embodiments may include a plurality of macro metal pads PM and a plurality of micro metal pads PU in an interface region 10 of the bottom-die 100. The plurality of macro metal pads PM may be templated, and the plurality of micro metal pads PU may be templated

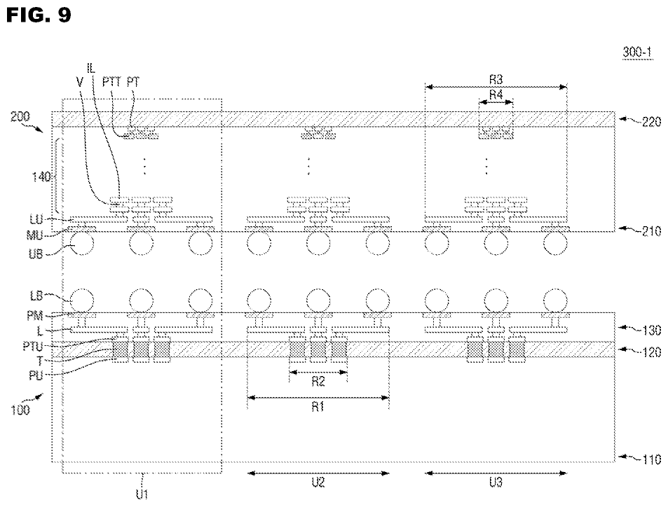

The plurality of macro metal pads PM may be arranged in an array form and may be disposed on an upper face R1 of the bottom-die 100. In an example shown in FIG. 1, the plurality of macro metal pads PM may be arranged in a 4×4 array. A micro bump (such as LB in FIG. 8) may be disposed on a respective macro metal pad PM (i.e., on the upper face of the bottom-die 100). The number of micro bumps may correspond to the number of the plurality macro metal pads PM.

For example, in an example shown in FIGS. 2 and 3, a plurality of macro metal pads PM1 to PM9 may be arranged in a 3×3 array, and a plurality of micro metal pads PU1 to PU9 may be also arranged in a 3×3 array. In FIG. 3, the macro metal pad PM3 is omitted for convenience of illustration.

The plurality of micro metal pads PU may be arranged in an array form and may be disposed on a keep-out zone bundle region R2 of a bottom face of the bottom-die 100. The keep-out zone bundle region R2 may be one keep-out zone of a plurality of keep-out zones, and may include a plurality of micro metal pads PU arranged in an array form and spaced apart from each other.

Each of the plurality of micro metal pads PU and the plurality of macro metal pads PM may be made of a conductive material, and examples of the conductive material may include nickel, copper, gold, solder, and the like. An insulating film may include, for example, at least one of silicon oxide, silicon nitride, silicon oxynitride, and a low-k material with a lower dielectric constant than that of silicon oxide. However, the present disclosure is not limited thereto.

In addition, the plurality of micro metal pads PU may be spaced apart from each other and may be electrically isolated from each other. The plurality of macro metal pads PM may be spaced apart from each other and may be electrically isolated from each other. To this end, an insulating material may be disposed between adjacent micro metal pads and between adjacent macro metal pads.

Referring to FIG. 2 and FIG. 3, the bottom-die 100 may further include a routing wiring layer including a plurality of routing metals L1 to L9, and a plurality of through silicon vias (TSVs) T1 to T9 connecting the routing metals L1 to L9 to the plurality of micro metal pads PU, respectively.

The plurality of routing metals L1 to L9 may be respectively disposed under the plurality of macro metal pads (e.g., macro metal pads PM1 to PM9) and may be electrically independently disposed each other. The number of the plurality of routing metals L1 to L9 may correspond to the number of the plurality of macro metal pads PM1 to PM9. A first end of a routing metal may be electrically connected to a respective macro metal pad PM, and a second end of the routing metal may be electrically connected to an end of a respective TSV. According to one embodiment, a plurality of contact areas C1 to C9 at positions corresponding to respective ends of respective routing metals of the plurality of routing metals L1 to L9 in FIG. 2 may indicate positions of a respective micro bump and a center of a respective macro metal pad. One end of each of the plurality of TSVs T1 to T9 may be connected to one end of a respective routing metal of the plurality of routing metals L1 to L9.

The plurality of routing metals L1 to L9 may be arranged radially and may be arranged in a symmetrical manner with other. In some embodiments, shapes of the routing metals may have a straight line shape, a rectangular shape, and a bent shape according to shapes of extensions between corresponding macro metal pads and corresponding micro metal pads.

According to some embodiments, the plurality of contact areas C1 to C9 may be disposed at positions having the same horizontal distance in each micro metal pad. The plurality of contact areas C1 to C9 may be disposed at positions radially spaced apart from each other by 45 degrees based on the center contact C5 of the keep-out zone bundle region R2. The plurality of routing wirings L1 to L9 may be arranged in a symmetrical manner to each other based on the arrangement of the plurality of contact areas C1 to C9 (in the example as shown, in an arrangement of L shaped patterns (also referred to as “elbow shaped patterns” or “bent shaped patterns”) facing each other).

As shown in FIG. 2, the routing metal L5 at the position corresponding to C5 is disposed at a position at which the micro metal pad PU5 and the macro metal pad PM5 overlap each other. Thus, the routing metal L5 may be formed in a rectangular shape. The macro metal pad PM7 may be disposed at an end of a diagonal line of the upper face. The micro metal pad PU7 may be disposed on the bottom face and in a center region of the interface region, and may be disposed inwardly of the end of the diagonal line. Thus, the routing metal at a position corresponding to C7 may be formed in a shape bent in a bi-directional manner. The macro metal pad PM4 may be disposed at an edge of the die 100-1 along the X direction and on the upper face. The micro metal pad PU4 may be disposed on the bottom face and in the center region of the interface region (i.e., inward of the edge in the X direction). Thus, the routing metal L4 at the position corresponding to C4 may be formed in a straight line shape. According to various embodiments, the routing metal L7 may be formed diagonally instead of being bent in the bi-directional manner.

Each of the plurality of TSVs T1 to T9 may be disposed under a respective end of each of the plurality of routing metals L1 to L9 and may extend in a stacking direction (e.g., in the vertical direction Z). The plurality of TSVs T1 to T9 may be respectively and electrically connected to each of the micro metal pads PU1 to PU9.

A spacing between adjacent micro metal pads (e.g., a spacing between PU1 and PU2) may be smaller than a spacing between adjacent macro metal pads (e.g., PM1 and PM2). Further, one micro metal pad (e.g., PU1) may have a smaller area size than that of one macro metal pad (e.g., PM1).

The plurality of micro metal pads PU1 to PU9 may be disposed in the keep-out zone bundle region R2. Each macro metal pad may be individually disposed in each of independent keep-out zone K1 to K9. Therefore, an area size of the keep-out zone bundle region R2 may be smaller than a total area size of the plurality of keep-out zones K1 to K9, and may be smaller than a total area size of the plurality of macro metal pads PM1 to PM9. Thus, the routing and placement for logic cells are less restricted by the interface region of the die. It is noted that the depiction of the plurality of keep-out zones is identified as K1 to K9. The plurality of keep-out zones may correspond to zones K1 to K4, K6 to K9, and R2 (i.e., K5 may correspond to keep-out zone bundle area R2).

According to some embodiments, the micro metal pad PU1, the TSV T1, the routing metal L1, and the macro metal pad PM1 may be connected to each other. A connected combination of the micro metal pad PU1, the TSV T1, the routing metal L1, and the macro metal pad PM1 may be electrically isolated from a connected combination of the micro metal pad PU2, the TSV T2, the routing metal L2, and the macro metal pad PM2, and so forth. In addition, a connected combination of a micro metal pad, a TSV, a routing metal, a macro metal pad, and a micro bump may be formed in a crown form structure having a narrow area bottom face and a wide area upper face. That is, in the interface region of the bottom-die 100, a connected combination of the micro metal pad to the macro metal pad may be structured in the crown form. That is, the templated micro metal pad may be disposed on a small area of the bottom face of the interface region U1 of the bottom-die 100. Thus, other logic components may be disposed in other areas of the bottom face thereof. Thus, a degree of freedom in a logic design may be improved.

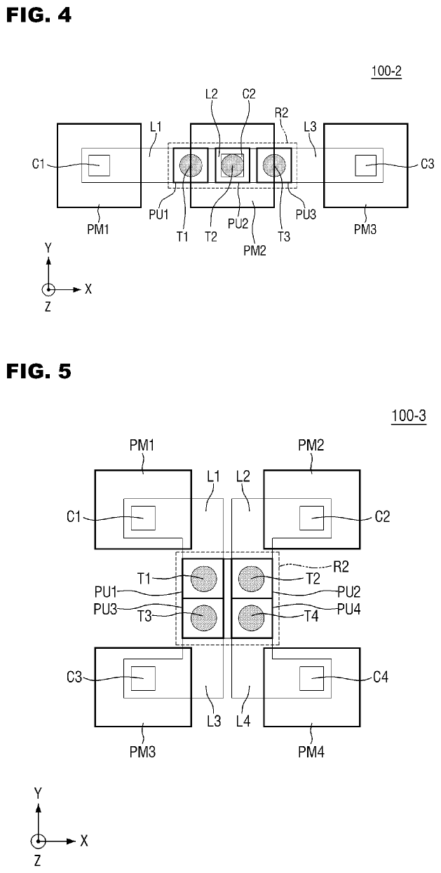

FIGS. 4, 5 and 6 are top views illustrating bottom-dies according to some embodiments. Repeated description of aspects set forth above may be omitted.

An array form of the plurality of micro metal pads disposed in the keep-out zone bundle region R2 may correspond to an arrangement form of the plurality of macro metal pads. The plurality of routing metals may be arranged radially and may be arranged symmetrically with each other and may be disposed in a routing wiring layer so as to connect the plurality of micro metal pads and the plurality of macro metal pads to each other, respectively.

Referring to FIG. 4, according to some embodiments, an interface region U1 of a bottom-die 100-2 may include a plurality of macro metal pads PM1 to PM3 arranged in a 3×1 array form, a plurality of routing metal L1 to L3, TSVs T1 to T3, and a plurality of micro metal pads PU1 to PU3 arranged in a 3×1 array form.

In the illustrated embodiment, each of the plurality of routing metals L1 to L3 may be formed in a straight-line shape or rectangular shape.

Referring to FIG. 5, according to some embodiments, an interface region U1 of the bottom-die 100-3 may include a plurality of macro metal pads PM1 to PM4 arranged in a 2×2 array form, a plurality of routing metals L1 to L4, a plurality of TSVs T1 to T4, and a plurality of micro metal pads PU1 to PU4 arranged in a 2×2 array form. In the illustrated embodiment, each of the plurality of routing metals L1 to L4 may be formed in a bent manner. The plurality of routing metals L1 to L4 may be arranged symmetrically with each other.

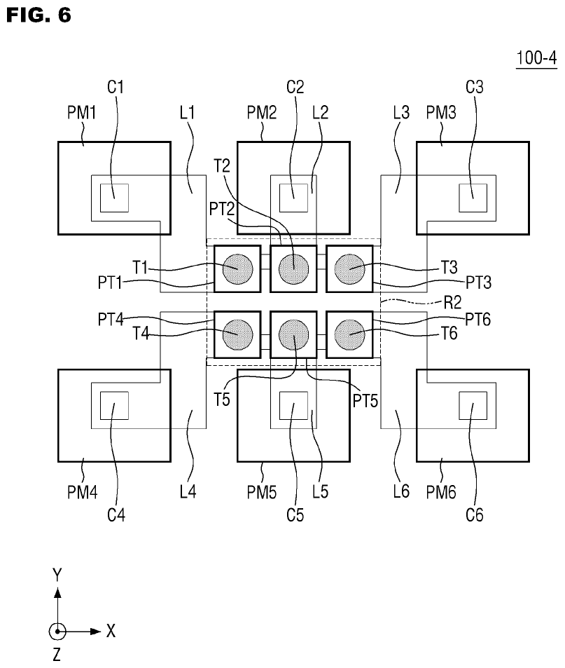

Referring to FIG. 6, according to some embodiments, an interface region U1 of a bottom-die 100-4 may include a plurality of macro metal pads PM1 to PM6 arranged in a 3×2 array form, a plurality of routing metals L1 to L6, TSVs T1 to T6, and a plurality of micro metal pads PU1 to PU6 arranged in a 3×2 array form. In the illustrated embodiment, the plurality of routing metals L1 to L6 may be arranged symmetrically with each other. The shapes of the plurality of routing metals L1 to L6 may be bent shapes (also referred to as angled shape) and straight-line shapes.

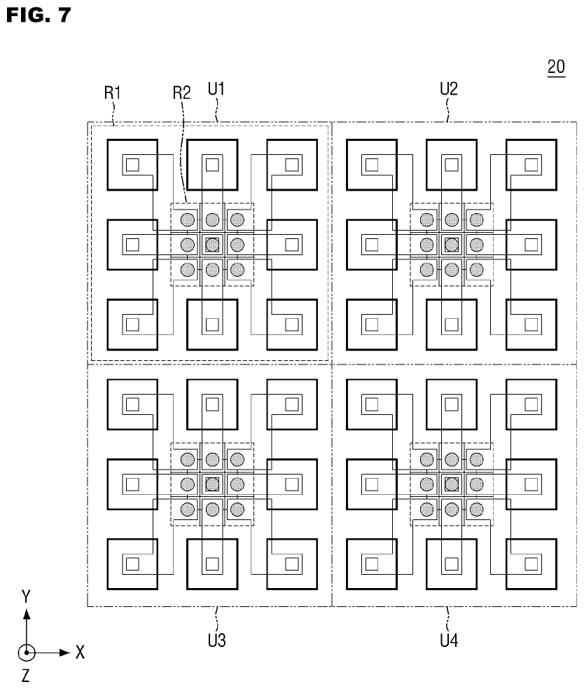

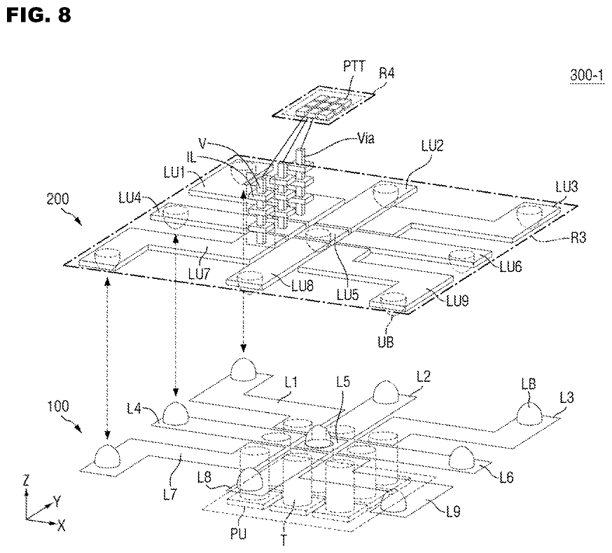

FIG. 7 is a top view illustrating a bottom-die according to some embodiments.

A stack type semiconductor device 20 may include a plurality of interface regions as described above with reference to FIGS. 3 to 6 according to some embodiments. For example, the plurality of interface regions U1, U2, U3, and U4 of the bottom-die of FIG. 3 may be arranged in a 2×2 array form.

According to some embodiments, the plurality of interface regions U1, U2, U3, and U4 may be arranged in a 2×2 array form in an adjacent manner to each other as shown. According to some further embodiments, the plurality of interface regions U1, U2, U3, and U4 may be arranged in a 2×2 array form so as to be spaced apart from each other by a predetermined distance.

The illustrated embodiment is intended only for convenience of description, and the scope of the present disclosure is not limited thereto.

FIG. 8 is a diagram illustrating a three-dimensional semiconductor device according to some embodiments. FIG. 9 is a cross-sectional view showing an interface region of FIG. 8 according to some embodiments. Repeated description of aspects set forth above may be omitted.

Referring to FIG. 8, in an interface region of a semiconductor device 300-1, the top-die 200 may be stacked on the bottom-die 100.

The top-die 200 may include a plurality of micro bumps UB, a plurality of macro metal pads (e.g., MU in FIG. 9), a plurality of routing wirings LU, and a plurality of micro metal pads PTT.

The number of the plurality of of the micro bumps UB, the plurality of the macro metal pads MU, the plurality of of the routing wirings LU, and the plurality of the micro metal pads PTT of the top-die 200 may be equal to the number of the plurality of micro bumps LB of the bottom-die 100. For example, when the plurality of micro bumps LB of the bottom-die 100 are arranged in in a 3×3 array form, the plurality of micro bumps UB of the top-die 200 may be arranged in a 3×3 array form.

The plurality of micro bumps UB may be disposed on the bottom face 210 of the top-die 200. Each micro bump of the plurality of micro bumps UB may be disposed at a position corresponding to each micro bump of the plurality of micro bumps LB of the bottom-die 100. The top-die 200 may include the plurality of macro metal pads MU respectively disposed at positions corresponding to the plurality of micro bump UBs on the bottom face 210 thereof. A routing wiring layer including the plurality of routing metals LU may be respectively stacked on the plurality of macro metal pads MU and may be arranged radially.

The plurality of macro metal pads MU may be disposed in independent keep-out zones spaced apart from each other, respectively. Each of the plurality of routing metals may extend on the same plane and in a direction from a macro metal pad to a micro metal pad. The plurality of routing metals may be isolated from each other. For example, the plurality of routing metals may have a rectangular shape, a straight shape and a bent shape based on shapes of extensions between the plurality of macro metal pads MU and the plurality of micro metal pads PTT. According to some embodiments, the arrangement form of the plurality of routing metals LU1 to LU9 of the top-die 200 may be the same or substantially the same as the arrangement form of the plurality of routing metals L1 to L9 of the bottom-die 100.

Referring to FIG. 9, the top-die 200 may further include at least one intermediate wiring layer 140 including an intermediate metal pad IL and vias V. The intermediate wiring layer 140 may include one intermediate metal pad and at least two vias V according to various embodiments. Unlike the bottom-die 100, in the top-die 200, the routing metal LU and the micro metal pad PTT may be connected to each other via the intermediate metal pad IL and the vias V instead of the TSV T.

The top-die 200 may include the micro metal pad PTT disposed in the keep-out zone bundle region R4 of the upper face 220 thereof. The keep-out zone bundle region R4 may be one keep-out zone, and may refer to a region in which the plurality of micro metal pads PTT are disposed. According to various embodiments, a connection area R3 of the bottom face of the top-die 100 may have the same area size that of a connection area R1 of the upper face of the bottom-die 200. The keep-out zone bundle region R4 of the top-die may have a smaller area size than that of the keep-out zone bundle region R2 of the bottom-die. That is, a spacing between adjacent micro metal pads PU of the bottom-die 100 may be larger than a spacing between adjacent micro metal pads PTT of the top-die 200. A spacing between adjacent macro metal pads PM of the bottom-die 100 may be equal to a spacing between adjacent macro metal pads MU of the top-die 200.

Therefore, a logic cell may be disposed on an area of each of the upper face 220 of the top-die 200 and the bottom face of the bottom-die 100 except for in the keep-out bundle region. Thus, the degree of freedom of the place and routing (PnR) may be improved.

According to some embodiments, the micro metal pad PTT, the intermediate wiring layer 140, the routing metal LU, and the macro metal pad MU may be connected to each other in a corresponding manner. A connected combination of the micro metal pad PTT, the intermediate wiring layer 140, the routing metal LU, and the macro metal pad MU may be electrically isolated from a connected combination of another micro metal pad, another intermediate wiring layer, another routing metal, and another macro metal pad. In addition, the connected combination of the micro metal pad PTT, the intermediate wiring layer 140, the routing metal LU, and the macro metal pad MU of the top-die 200 may have a structure of an inverted balloon form with a wide area bottom face and a small area upper face, or may have a baobab tree structure. That is, the connected combination of the micro metal pad to the macro metal pad in the interface region of the top die 200 may have the inverted balloon form structure or the baobab tree structure. The micro metal pad may be disposed on a small area of the upper face of the interface region U1 of the top-die 200 such that other logic components may be disposed on the remaining area of the upper face. The degree of freedom in terms of logic design may be improved. In addition, the top-die and the bottom-die may have the templates of the structures (e.g., the crown form and a baobab tree form) symmetrical with each other. Thus, the degree of freedom of the PnR of the logic cell may be improved while the top and bottom dies electrically communicate a signal with each other in a reliable manner.

According to some embodiments, the bottom-die 100 may further include an intermediate pad PTU disposed between the TSV T and the routing metal L. The intermediate pad PTU together with a via may electrically connect one end of the routing metal L to one end of the TSV T.

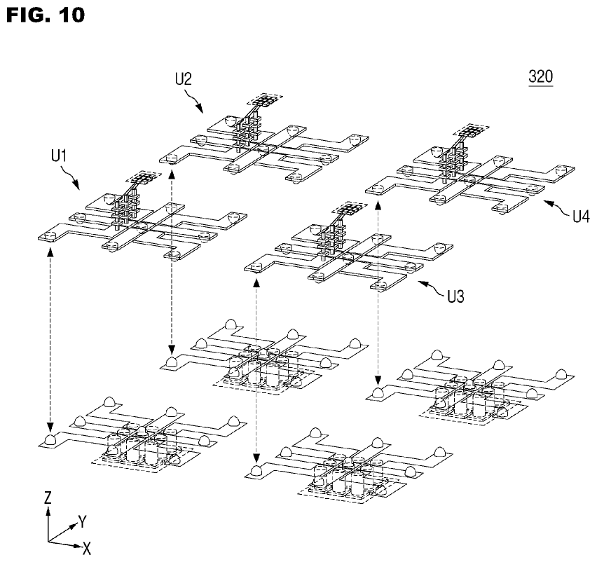

FIG. 10 is a diagram illustrating an interface region of a semiconductor device according to some embodiments.

According to some embodiments, a semiconductor device 320 may include a plurality of interface regions U1, U2, U3, and U4. For example, the plurality of interface regions U1, U2, U3, and U4 may be arranged in an array form in an adjacent manner to each other or may be arranged so as to be spaced apart from each other by a predefined distance.

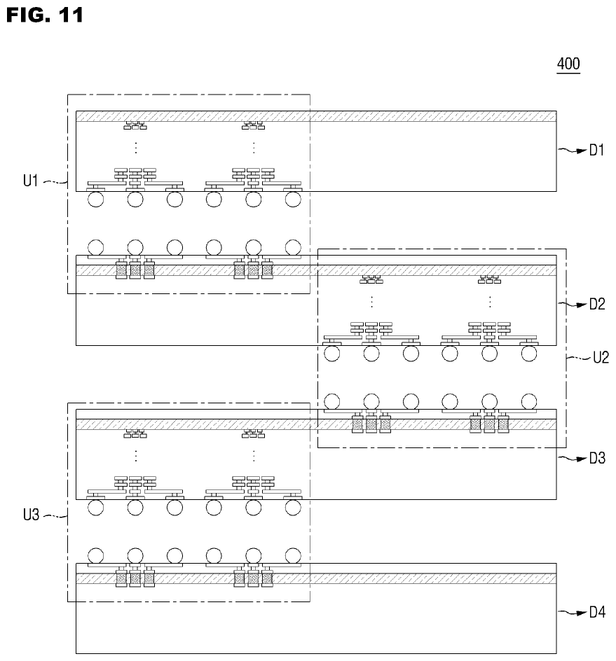

FIG. 11 is a cross-sectional view illustrating an interface region of a semiconductor device according to some embodiments.

According to some embodiments, a semiconductor device 400 may include a plurality of interface regions U1, U2, and U3. For example, an example in which four dies D1, D2, D3, and D4 are stacked will be described. The first interface region U1 may be an interface region between the first die D1 and the second die D2, the second interface region U2 may be an interface region between the second die D2 and the third die D3, and the third interface region U3 may be an interface region between the third die D3 and the fourth die D4.

According to some embodiments, the interface regions between the vertically stacked dies may be alternately arranged with each other so as not to overlap each other. For example, the first interface region U1 and the second interface region U2 may not overlap each other in the Z-axis direction. The second interface region U2 and the third interface region U3 may not overlap each other in the Z-axis direction.

Alternatively, according to some embodiments, the first interface region U1 and the second interface region U2 may not fully overlap each other but may partially overlap each other.

Alternatively, the first interface region U1 and the second interface region U2 may be offset relative to each other by a preset distance, based on the number of the stacked dies.

Each of the embodiments provided in the above description is not excluded from being associated with one or more features of another example or another embodiment also provided herein or not provided herein but consistent with the disclosure

While the disclosure has been particularly shown and described with reference to embodiments thereof, it will be understood that various changes in form and details may be made therein without departing from the spirit and scope of the following claims.

What is claimed is:

1. A semiconductor device comprising:
a first die comprising:
a plurality of first micro bumps on a first upper face of the first die;
a plurality of first macro metal pads at positions respectively corresponding to the plurality of first micro bumps;
a first routing wiring layer comprising a plurality of first routing metals, wherein a first end of each of the plurality of first routing metals is respectively under the plurality of first macro metal pads;
a plurality of through silicon vias (TSVs), wherein first ends of the plurality of TSVs are respectively connected to second ends of the plurality of first routing metals, and wherein each of the plurality of TSVs extends downward from the respective second ends of the plurality of first routing metals;
a first plurality of keep-out zones comprising a first keep-out zone bundle region; and
a plurality of first micro metal pads in the first keep-out zone bundle region and respectively under second ends of the plurality of TSVs,
wherein a first area size of the first keep-out zone bundle region is smaller than a total area size of the first plurality of keep-out zones.

2. The semiconductor device of claim 1, wherein each of the second ends of the plurality of TSVs is in the first keep-out zone bundle region.

3. The semiconductor device of claim 1, wherein each first routing metal of the plurality of first routing metals is configured to connect a respective first macro metal pad of the plurality of first macro metal pads to a respective TSV of the plurality of TSVs.

4. The semiconductor device of claim 3, wherein the first die further comprises:
a plurality of first vias respectively under the second ends of the plurality of first routing metals; and
a plurality of intermediate pads respectively connecting the plurality of first vias to the first ends of the plurality of TSVs.

5. The semiconductor device of claim 1, wherein each of the first macro metal pads of the plurality of first macro metal pads has a larger size than each of the first micro metal pads of the plurality of first micro metal pads.

6. The semiconductor device of claim 1, further comprising:
a second die comprising:
a plurality of second micro bumps on a bottom face of the second die at positions respectively corresponding to positions of the plurality of first micro bumps;
a plurality of second macro metal pads respectively on the plurality of second micro bumps at positions respectively corresponding to the plurality of second micro bumps;
a second routing wiring layer on upper faces of the plurality of second macro metal pads and comprising a plurality of second routing metals, wherein the plurality of second routing metals are arranged radially and are electrically isolated from each other;
a second plurality of keep-out zones comprising a second keep-out zone bundle region,
a plurality of second micro metal pads on an upper face of the second die, and in the second keep-out zone bundle region; and
at least one intermediate wiring layer comprising a plurality of second vias and a plurality of intermediate wirings configured to respectively connect the plurality of second routing metals to the plurality of second micro metal pads.

7. The semiconductor device of claim 6, wherein a second area size of the second keep-out zone bundle region is smaller than a total area size of the second plurality of keep-out zones.

8. A three-dimensionally stacked semiconductor device comprising:
a plurality of first micro bumps arranged in an M×N array on an upper face of a bottom die, wherein each of M and N is a natural number of 1 or greater;
a plurality of first macro metal pads respectively corresponding to the plurality of first micro bumps, such that the plurality of first micro bumps are on respective upper faces of the plurality of first macro metal pads;
a first routing wiring layer comprising a plurality of first routing metals, wherein a first end of each of the plurality of first routing metals is radially arranged under the plurality of first macro metal pads, respectively;
a plurality of through silicon vias (TSVs), wherein first ends of the plurality of TSVs are respectively connected to second ends of the plurality of first routing metals, and wherein each of the plurality of TSVs extends downward from the respective second ends of the plurality of first routing metals; and
a plurality of first micro metal pads in a first keep-out zone bundle region and respectively under the second ends of the plurality of TSVs,
wherein a first area size of the first keep-out zone bundle region is smaller than a total area size of the plurality of first macro metal pads.

9. The semiconductor device of claim 8, wherein each of the plurality of first micro bumps is respectively connected to each of the plurality of first micro metal pads via a respective first micro metal pad of the plurality of first macro metal pads, a respective first routing metal of the plurality of first routing metals, and a respective TSV of the plurality of TSVs, and
wherein each of the plurality of first micro bumps is electrically insulated from each other.

10. The semiconductor device of claim 8, wherein the plurality of first micro metal pads are on a bottom face of the bottom die and are arranged in a M×N array.

11. The semiconductor device of claim 8, wherein the second ends of the plurality of TSVs are spaced apart from each other and are in the first keep-out zone bundle region.

12. The semiconductor device of claim 11, wherein a spacing between adjacent first macro metal pads of the plurality of first macro metal pads is greater than a spacing between adjacent first micro metal pads of the plurality of first micro metal pads.

13. The semiconductor device of claim 8, wherein the plurality of first routing metals are electrically isolated from each other, and
wherein each of the plurality of first routing metals extends from respective first macro metal pads of the plurality of first macro metal pads to respective first micro metal pads of the plurality of first micro metal pads.

14. The semiconductor device of claim 13, wherein each first routing metal of the plurality of first routing metals is formed in a bent shape or a straight shape and configured to connect a respective first macro metal pad of the plurality of first macro metal pads to a respective TSV of the plurality of TSVs.

15. The semiconductor device of claim 8, wherein a top die is on the bottom die,
wherein the top die comprises:
a plurality of second micro metal pads in an upper face of the top die;
a plurality of second macro metal pads in a bottom face of the top die;
a plurality of second micro bumps on the bottom face of the top die and each at a position respectively corresponding to the plurality of first micro bumps; and
a plurality of second routing wirings respectively connected to the plurality of second macro metal pads and the plurality of second micro metal pads, and
wherein the plurality of second routing wirings are electrically isolated from each other.

16. The semiconductor device of claim 15, wherein the bottom die is configured such that a connected combination of each first micro metal pad of the plurality of first micro metal pads to each first macro metal pad of the plurality of first macro metal pads comprises a crown structure, and
wherein the top die is configured such that a connected combination of each second micro metal pad of the plurality of second micro metal pads to each second macro metal pad of the plurality of second macro metal pads comprises a balloon structure.

17. A semiconductor device comprising:
a first bottom die;
a first upper die on an upper face of the first bottom die; and
a first interface region between the first upper die and the first bottom die,
wherein the first interface region comprises:
a plurality of first micro bumps on the upper face of the first bottom die;
a plurality of first macro metal pads on respective upper faces of the plurality of first macro metal pads, wherein adjacent first macro metal pads of the plurality of first macro metal pads are spaced from each other by a first spacing;
a first routing wiring layer comprises a plurality of first routing metals, wherein first ends of the plurality of first routing metals are respectively and radially arranged under the plurality of first macro metal pads;
a plurality of through silicon vias (TSVs) respectively extending downward from second ends of the plurality of first routing metals, wherein first ends of the plurality of TSVs are respectively connected to the second ends of the plurality of first routing metals; and
a plurality of first micro metal pads in a first keep-out zone bundle region and respectively under second ends of the plurality of TSVs,
wherein adjacent first micro metal pads of the plurality of first micro metal pads are spaced from each other by a second spacing, and
wherein the second spacing is smaller than the first spacing.

18. The semiconductor device of claim 17, wherein, in a stacked direction, the first interface region does not overlap a second interface region between the first upper die and a second upper-die on the first upper die.

19. The semiconductor device of claim 17, wherein a first area size of the first keep-out zone bundle region is smaller than a total area size of the plurality of first macro metal pads.

20. The semiconductor device of claim 17, wherein each first routing metal of the plurality of first routing metals is formed in a bent shape or a straight shape and configured to connect a respective first macro metal pad of the plurality of first macro metal pads to a respective TSV of the plurality of TSVs.

21. The semiconductor device of claim 17, wherein the first interface region further comprises:
a plurality of second micro metal pads in an upper face of the first upper die;
a plurality of second macro metal pads in a bottom face of the first upper die;
a plurality of second micro bumps on the bottom face of the first upper die and at positions respectively corresponding to the plurality of first micro bumps; and
a plurality of second routing wirings respectively connected to the plurality of second macro metal pads and the plurality of second micro metal pads,
wherein the plurality of second routing wirings are electrically isolated from each other.
